(19) United States
(12) Patent Application Publication
(10) Pub. No.: US 2003/0070790 A1
(43) Pub. Date: Apr. 17, 2003

(54) Heat sink/clip assembly for chip mounted on electronic card

(76) Inventors: Rong-Che Chen, Taipei (TW); Tien-Lu Kao, Cypress, CA (US); Choon-Hwa Tay, Cypress, CA (US)

Correspondence Address: WEI TE CHUNG, FOXCONN INTERNATIONAL, INC., 1650 MEMOREX DRIVE, SANTA CLARA, CA, 95050, US

(21) Appl. No.: 09/976,970

(22) Filed: Oct. 11, 2001

(51) Int. Cl. F28F 7/00; H05K 7/20; H01L 23/34

(52) U.S. Cl. 165/80.3; 165/185; 257/719; 257/722; 361/704

(57) ABSTRACT

A heat sink/clip assembly includes a clip (10) attaching a heat sink (30) to a chip (40) which is mounted on an electronic card (50). The clip includes a middle portion (11), two spring arms (14), and first and second legs (16, 18). First and second catches (17, 19) extend horizontally inwardly and toward each other from bottom ends of the first and second legs respectively. The first catch is longer than the second catch. The middle portion of the clip is accommodated in a channel (36) of the heat sink. A pair of notches (52) is defined in opposite side surfaces of the electronic card. The first catch is inserted into one of the notches. Then an opposite end of the clip is depressed, and the second catch is engaged in the other notch. Therefore the clip firmly attaches the heat sink to the chip.

### BACKGROUND OF THE INVENTION

1. Field of the invention

The present invention relates to means for securing heat sinks, and particularly to a heat sink assembly including a clip for attaching a heat sink to an electronic device such as a chip on an electronic card.

2. Prior art

Present-day monolithic semiconductor devices such as microprocessors frequently have high current path densities. This results in large amounts of heat being generated in relatively small regions. Heat produced by large semiconductor devices is often not adequately removed either by natural air convection or by powered ventilation such as a fan. A heat sink is often directly attached to the device to effect cooling by way of convection. The attachment can be by way of a bonding process, such as an adhesive. However, because of the permanent nature of such attachment, bonding is generally not desirable. If a malfunctioning chip is to be discarded, it is impractical to throw away the heat sink too. It has therefore been found desirable to attach the heat sink to the chip by mechanical means such as a retainer clip.

FIG. 4 shows a conventional clip 1 attaching a heat sink 2 to a chip 3. The chip 3 is mounted to an electronic card 4, and the heat sink 2 is attached to a top surface of the chip 3. Two through holes 5 are defined in the electronic card 4, in the vicinity of diagonally opposite comers of the chip 3. Each through hole 5 receives a corresponding leg 6 of the clip 1 therein. A hook (not visible) at the end of each leg 6 engages a bottom surface of the electronic card 4, thereby pressing the heat sink 2 onto the chip 3. Unfortunately, this means of attachment needs at least one pair of through holes in an electronic card. In many instances, the through holes must be created by drilling. However, for many high-density electronic cards, there is often no space available for drilling such holes.

Therefore, an improved means for attaching a heat sink to a chip mounted on an electronic card is desired.

### BRIEF SUMMARY OF THE INVENTION

Accordingly, an object of the present invention is to provide a heat sink/clip assembly for readily and firmly attaching a heat sink to a chip of an electronic card.

Another object of the present invention is to provide a heat sink clip having simplified and cost-effective means for engaging with an electronic card.

To achieve the above-mentioned objects, a heat sink/clip assembly comprises a clip attaching a heat sink to a chip which is mounted on an electronic card. The clip comprises a middle portion, two spring arms, and first and second legs. First and second catches extend horizontally inwardly and toward each other from bottom ends of the first and second legs respectively. The first catch is longer than the second catch. The middle portion of the clip is accommodated in a channel of the heat sink. A pair of notches is defined in opposite side surfaces of the electronic card. The first catch is inserted into one of the notches. Then an opposite end of the clip is depressed, and the second catch is engaged in the other notch. Therefore the clip firmly attaches the heat sink to the chip.

Other objects, advantages and novel features of the present invention will be drawn from the following detailed description of a preferred embodiment of the present invention with the attached drawings, in which:

### BRIEF DESCRIPTION OF THE DRAWINGS

FIG. 1 is an exploded view of a heat sink assembly of the present invention;

FIG. 2 is a perspective view of a heat sink clip of FIG. 1;

FIG. 3 is an assembled view of FIG. 1; and

FIG. 4 is an assembled view of a conventional heat sink assembly.

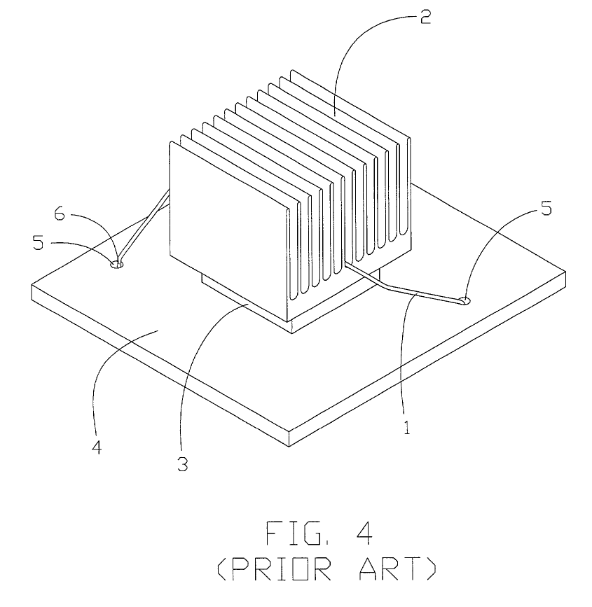

### DESCRIPTION OF THE PREFERRED EMBODIMENT

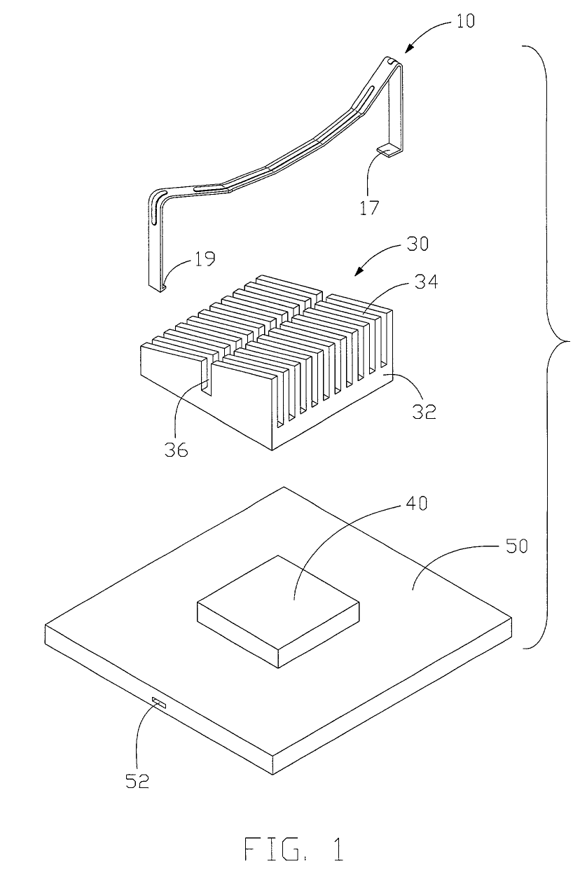

Referring to FIG. 1, a heat sink clip 10 in accordance with the present invention is used to engage with an electronic card 50. The heat sink clip 10 thereby firmly attaches a heat sink 30 to a chip 40 which is mounted on the electronic card 50. A pair of notches 52 (only one visible) is defined in two opposite side surfaces of the electronic card 50. The heat sink 30 includes a base 32, and a plurality of fins 34 extending upwardly from the base 32. A channel 36 is defined transversely through the fins 34 across a central portion of the heat sink 30.

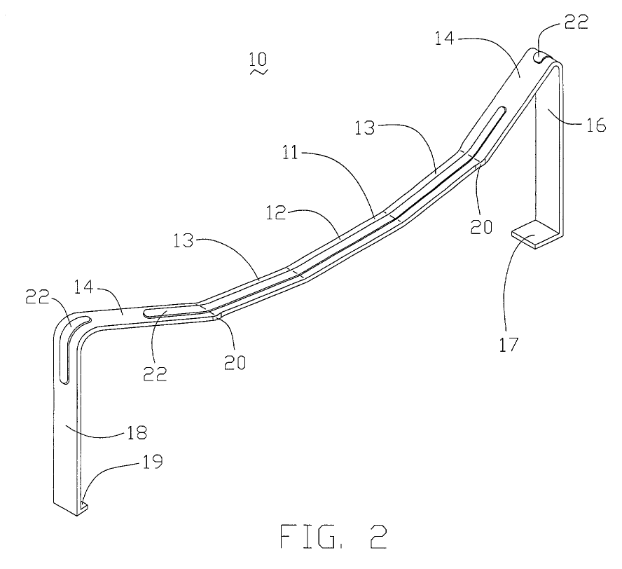

Referring also to FIG. 2, the heat sink clip 10 comprises a middle portion 11, two spring arms 14 extending outwardly and upwardly from opposite ends of the middle portion 11 respectively, and first and second legs 16, 18 depending from distal ends of the spring arms 14 respectively. A first catch 17 extends horizontally inwardly from a bottom end of the first leg 16. A second catch 19 extends horizontally inwardly from a bottom end of the second leg 18. The first and second catches 17, 19 thus extend toward each other and generally oppose each other. The first catch 17 is longer than the second catch 19. The middle portion 11 comprises a horizontal pressing portion 12, and a pair of spring portions 13 extending outwardly and slightly upwardly from opposite ends of the pressing portion 12 respectively. A width of the middle portion 11 is less than that of the spring arms 14. A pair of shoulders 20 is thereby formed at a junction between each spring portion 13 and the corresponding spring arm 14. The width of the middle portion 11 is slightly less than a width of the channel 36 of the heat sink 30, to facilitate accommodation of the clip 10 in the channel 36.

A longitudinal reinforcing rib 22 is integrally formed along the middle portion 11 and an adjacent portion of each spring arm 14. Another reinforcing rib 22 is integrally formed on the first leg 16 and an adjacent portion of the corresponding spring arm 14. Still another reinforcing rib 22 is integrally formed on the second leg 18 and an adjacent portion of the corresponding spring arm 14.

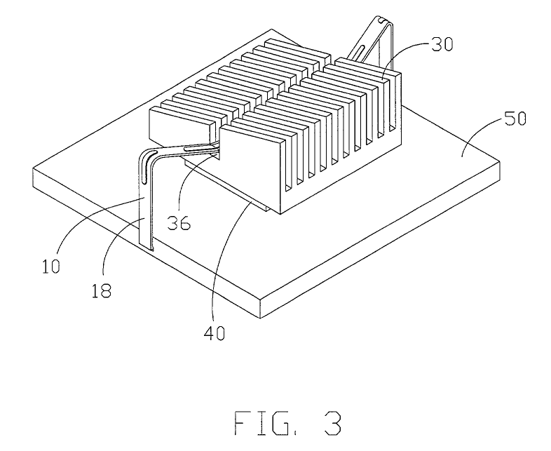

Referring also to FIG. 3, in assembly, the heat sink 30 is placed onto the chip 40. The middle portion 11 of the clip 10 is accommodated in the channel 36 of the heat sink 30. The shoulders 20 of the clip 10 respectively abut against outmost fins 34 adjacent the channel 36, therefore preventing the heat sink 30 from moving laterally relative to the clip 10. The first catch 17 is inserted into the corresponding notch 52 of the electronic card 50. Then an opposite end of the clip 10 is depressed. The second catch 19 is pulled outwardly and snappingly inserted into the other notch 52 of the electronic card 50.

Manufacturing of the clip 10 is simple and therefore very economical. In addition, the present invention utilizes the notches 52 at the side surfaces of the electronic card 50, the notches being pre-existing. Thus the present invention enables the clip 10 to be fixed to the electronic card 50 without the need for drilling through holes in the electronic card 50.

It is understood that the invention may be embodied in other forms without departing from the spirit thereof. Thus, the present example and embodiment are to be considered in all respects as illustrative and not restrictive, and the invention is not to be limited to the details given herein.

What is claimed is:

1. A heat sink assembly comprising:
an electronic card having two notches defined in opposite sides thereof;
a chip mounted on the electronic card;
a heat sink mounted to a top face of the chip, the heat sink comprising a base and a plurality of fins extending upwardly from the base, a channel being defined through the fins; and
a clip received in the channel and pressing the heat sink onto the chip, the clip comprising a middle portion, two spring arms extending outwardly and upwardly from opposite ends of the middle portion, two legs respectively depending from the spring arms, and two opposing catches respectively extending inwardly from the legs, wherein the catches engage in the corresponding notches of the electronic card.

2. The heat sink assembly as described in claim 1, wherein one of the catches is longer than the other catch.

3. The heat sink assembly as described in claim 1, wherein a width of the middle portion of the clip is less than a width of the spring arms, a pair of shoulders is thereby formed at each junction between the middle portion and each spring arm, and the shoulders abut against outmost fins of the heat sink thereby prevent the heat sink from moving laterally.

4. The heat sink assembly as described in claim 1, wherein the width of the middle portion of the clip is slightly less than a width of the channel of the heat sink, and the middle portion is accommodated in the channel.

5. The heat sink assembly as described in claim 1, wherein the middle portion comprises a pressing portion and two spring portions extending outwardly and upwardly from opposite ends of the pressing portion.

6. The heat sink assembly as described in claim 1, wherein a reinforcing rib is integrally formed on the middle portion and an adjacent portion of each spring arm, another reinforcing rib is integrally formed on the first leg and an adjacent portion of the corresponding spring arm, and still another reinforcing rib is integrally formed on the second leg and an adjacent portion of the corresponding spring arm.

7. A heat sink assembly comprising:
an electronic card defining two notches in two sides thereof,
a chip mounted on the electronic card;
a heat sink mounted on the chip, the heat sink comprising a base in contact with the chip and a plurality of fins projecting upwardly from the base; and
a clip pressing the heat sink onto the chip, the clip comprising a middle portion received in the fins, two spring arms extending outwardly and upwardly from opposite ends of the middle portion, and two legs respectively depending from the spring arms, each leg forming a catch engaging in a corresponding notch of the electronic card.

8. The heat sink assembly as described in claim 7, wherein one of the catches is longer than the other catch.

9. The heat sink assembly as described in claim 8, wherein a pair of shoulders is formed at each junction between the middle portion and each spring arm.

10. The heat sink assembly as described in claim 9, wherein reinforcing ribs are formed on the clip.
